(19) United States
(12) Patent Application Publication
(10) Pub. No.: US 2021/0112662 A1
(43) Pub. Date: Apr. 15, 2021

(54) WAFER TYPE SENSOR UNIT AND WAFER TYPE SENSOR UNIT MANUFACTURING METHOD

(71) Applicant: SEMES CO., LTD., Cheonan-si (KR)

(72) Inventors: Yong-Jun SEO, Hwaseong-si (KR); Sanghyun SON, Busan (KR); Sangmin HA, Daegu (KR); Hyeongjun CHO, Seoul (KR); Dongok AHN, Anyang-si (KR)

(73) Assignee: SEMES CO., LTD., Cheonan-si (KR)

(21) Appl. No.: 17/069,977

(22) Filed: Oct. 14, 2020

(30) Foreign Application Priority Data
Oct. 14, 2019 (KR) 10-2019-0126742

(51) Int. Cl. H05K 1/18; H01L 21/67

(52) U.S. Cl. CPC H05K 1/181; H05K 2201/10151; H01L 21/67253

(57) ABSTRACT

Disclosed is a wafer-type sensor unit. The wafer-type sensor unit according to an embodiment of the inventive concept may include a circuit board and an electronic element including a sensor installed on the circuit board. The electronic element may be disposed on the circuit board such that a center of gravity of the wafer-type sensor unit is provided to a center part of the sensor unit. The electronic element may further include a power supply unit and a signal processing unit processing a signal on the circuit board. The wafer-type sensor unit may further include one or more dummy elements installed on the circuit board.

### CROSS-REFERENCE TO RELATED APPLICATIONS

A claim for priority under 35 U.S.C. § 119 is made to Korean Patent Application No. 10-2019-0126742 filed on Oct. 14, 2019, in the Korean Intellectual Property Office, the entire contents of which are hereby incorporated by reference.

### BACKGROUND

Embodiments of the inventive concept described herein relate to a wafer-type sensor unit and a manufacturing method of the wafer-type sensor unit, and more particularly, relate to a wafer-type sensor unit and a manufacturing method in which the center of gravity is provided to the center part of the wafer-type sensor unit.

In manufacturing, semiconductors generally go through a number of processes such as an optical process, a deposition and growth process, an etching process, and the like. Each process in the semiconductor manufacturing process needs to carefully monitor process conditions and operating conditions of equipment. For example, while the temperature, gas injection state, pressure state, plasma density, or exposure distance of a chamber or wafer is controlled, precise monitoring is essential for optimal semiconductor yield.

When an error occurs in process conditions associated with the temperature, plasma, pressure, flow volume, gas, or the like or when the equipment malfunctions, many failures may occur. Accordingly, this is fatal to the overall yield.

Conventionally, streamlined sensors have been used to measure the pressure and distribution of chemicals in facilities. The streamlined sensors are not implemented in the form of a wafer, and thus it has been difficult for a robot to transfer a wafer. Also, there has been a difficulty that streamlined sensors are fixed to a chuck. To overcome the difficulty, wafer-shaped sensors have been developed.

The wafer-type sensor refers to a sensor with the shape of a wafer. The wafer-type sensor may directly sense process conditions (temperature or pressure, gas or plasma, or the like) in the semiconductor manufacturing process in the chamber, using each sensor while various sensors is equipped on a circuit board having the shape of a wafer. However, because commercially available wafer-type sensors are thick and heavy and have a structure in which the center of gravity is not matched, it is difficult to operate a robot that moves wafers, to fix a chuck, and to use a spinner.

### SUMMARY

Embodiments of the inventive concept provide a wafer-type sensor unit of which the center of gravity is capable of being concentrated on the center part.

Problems to be solved by the inventive concept are not limited to the above-described problem, and other problems not mentioned herein may be clearly understood from this specification and the accompanying drawings by those skilled in the art to which the inventive concept pertains.

Disclosed is a wafer-type sensor unit.

According to an exemplary embodiment, a wafer-type sensor unit may include a circuit board and an electronic element including a sensor installed on the circuit board. The electronic element may be disposed on the circuit board such that a center of gravity of the wafer-type sensor unit is provided to a center part of the sensor unit.

The electronic element may further include a power supply unit and a signal processing unit processing a signal on the circuit board.

The wafer-type sensor unit may further include one or more dummy elements installed on the circuit board.

The one or more dummy elements may be elements having a specific weight.

A wiring may not be connected to the one or more dummy elements.

The elements having the specific weight may be made of one of resin, ceramic, and carbon as a raw material.

The one or more dummy elements may be disposed on the circuit board such that the center of gravity of the wafer-type sensor unit in which the one or more dummy elements are arranged is provided to the center part of the sensor unit.

According to an exemplary embodiment, disclosed is a manufacturing method of a wafer-type sensor unit.

A manufacturing method of a wafer-type sensor unit may include arranging electronic elements included on the wafer-type sensor unit depending on an element arrangement rule and determine whether a center of gravity of the wafer-type sensor unit in which the electronic elements are arranged is provided to a center part of the sensor unit.

The manufacturing method may further include causing the center of gravity of the wafer-type sensor unit to be provided to the center part of the sensor unit by arranging one or more dummy elements in the wafer-type sensor unit when the center of gravity of the wafer-type sensor unit is not provided to the center part of the sensor unit.

The manufacturing method may further include coating a surface of the wafer-type sensor unit when the center of gravity of the wafer-type sensor unit is provided to the center part of the sensor unit.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view illustrating an example in which a center of gravity does not coincide in a conventional wafer-type sensor unit;

FIG. 2 is an example in a wafer-type sensor unit according to an embodiment of the inventive concept;

FIG. 3 is an example in a wafer-type sensor unit according to another embodiment of the inventive concept; and

FIG. 4 is a flowchart illustrating a manufacturing method of a wafer-type sensor unit according to an embodiment of the inventive concept.

### DETAILED DESCRIPTION

According to an embodiment of the inventive concept, other advantages and features and methods of accomplishing the same may be understood more readily with reference to the following detailed description of an embodiment and the accompanying drawings. The inventive concept, however, may be embodied in various different forms, and should not be construed as being limited only to the illustrated embodiments. Rather, these embodiments are provided as examples so that the disclosure will be thorough and complete, and will fully convey the category of the inventive concept to those skilled in the art. The inventive concept may be defined by scope of the claims. Meanwhile, the terminology used herein to describe embodiments of the inventive concept is not intended to limit the scope of the inventive concept.

Even though it is not defined, all terms (including technical or scientific terms) used herein, all terms have the same meaning as being generally accepted by the general technology in the art belonging to inventive concept. Terms defined by general dictionaries may be construed as having the same meaning as the related technology and/or body of this application, and will not be conceptualized or construed excessively formally, even though being not clearly defined herein.

The terms used in the specification are provided to describe the embodiments, not to limit the inventive concept. In the specification, the singular forms include plural forms unless particularly mentioned. The terms “comprises” and/or various conjugated forms of this verb such as ‘inclusion’, ‘comprising’, ‘including’, and ‘containing’ used herein does not exclude presence or addition of one or more other different compositions, ingredients, components, steps, operations, and/or elements in addition to the aforementioned compositions, ingredients, components, steps, operations, and/or elements. In the present specification, the term ‘and/or’ refers to each of the listed configurations or various combinations thereof.

It will be understood that, even though the terms “first,” “second,” “A,” “B,” etc. may be used herein in reference to elements of the inventive concept, such elements should not be construed as being limited by these terms. These terms are only used to distinguish one element from the other. For example, without departing the scope of the inventive concept, a first element may be referred to as a second element, and similarly, a second element may be referred to as a first element.

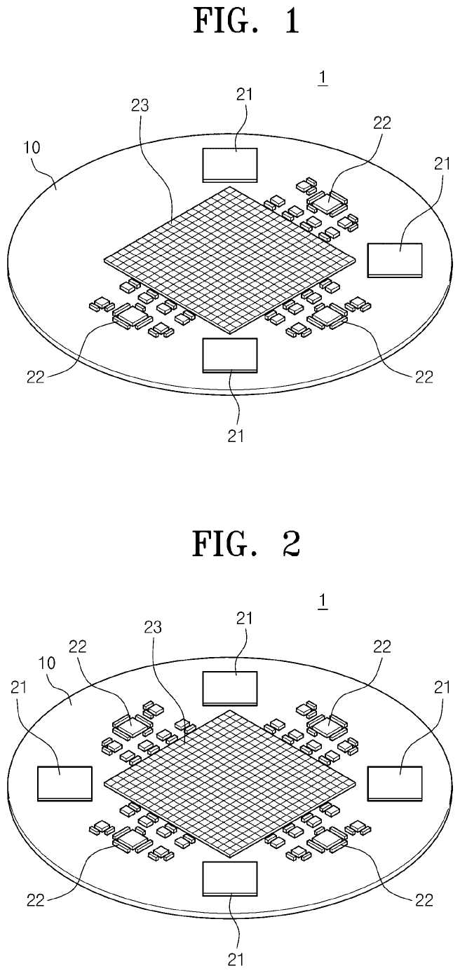

FIG. 1 is a view illustrating an example in which the center of gravity does not coincide in a conventional wafer-type sensor unit 1.

The wafer-type sensor unit 1 according to FIG. 1 may include a circuit board 10 and an electronic element 20. The circuit board 10 may be located in a lower portion of the wafer-type sensor unit 1. The circuit board 10 may be a PCB substrate. The circuit board 10 may have the shape of a wafer. The circuit board 10 may be formed in the size and shape corresponding to a wafer. The electronic element 20 may be variously disposed on the circuit board 10. The electronic element 20 capable of being arranged in the wafer-type sensor unit 1 may include a power supply unit 21, a signal processing unit 22, and a sensor unit 23. The electronic element 20 capable of being arranged on the circuit board 10 of the wafer-type sensor unit 1 is not shown, but may further include a wiring for connecting the electronic elements 20, a microcontroller unit (MCU), and the like. The power supply unit 21 may include a battery that provides an operating power supply. The sensor unit 23 may include a sensor capable of sensing various conditions. According to an example, the sensor unit 23 may include a temperature sensor, a pressure sensor, and the like. The signal processing unit 22 may perform signal processing on pieces of information received from the sensor unit 23. The signal processing unit 22 may include a communication unit that transmits information, or the like. According to an example, the chemical in the semiconductor facility may be measured by integrating a large-scaled matrix pressure sensor on the wafer in the wafer-type sensor unit 1. In addition, various physical quantity sensors may be included to sense leveling, vibration, temperature, pressure, gas, or the like.

According to the wafer-type sensor unit 1 disclosed in FIG. 1, the electronic elements 20 are arranged on the circuit board 10. More specifically, the three power supply units 21, the three signal processing units, and the sensor unit 23 located in the center part are disclosed in the wafer-type sensor unit 1 according to FIG. 1.

According to the arrangement structure of the electronic elements 20 illustrated in the wafer-type sensor unit 1 disclosed in FIG. 1, the power supply unit 21 and the signal processing unit 22 are arranged to be skewed to the right side of the wafer-type sensor unit 1, and thus are skewed to the right in consideration of the center of gravity in the wafer-type sensor unit 1 according to FIG. 1. As such, when the center of gravity of the wafer-type sensor unit 1 is not located in the center part but is skewed in any direction, the role of the wafer-type sensor may not be performed properly. When the center of gravity of the wafer-type sensor unit 1 is skewed in any direction, because there is the difficulty in the spin in a spinner facility or being fixed to the chuck, the center of gravity of the wafer-type sensor unit 1 needs to be fixed to the center part.

The fact that the center of gravity is located in the center part of the sensor unit means that the center of gravity is located within a specific area based on the center point of the wafer-type sensor unit 1. According to an example, the fact that the center of gravity is located in the center part of the sensor unit means that the center of gravity is located within an area of (0.1R)\hat{ }2*^{π} based on the center point of the wafer-type sensor unit 1, assuming that the radius of the wafer-type sensor unit 1 is R.

Generally, in a wafer-type sensor, the sensor unit 23 and signal processing unit 22 are uniformly arranged with the center of the wafer-type sensor over the front of the circuit board 10. However, when the wafer-type sensor performs a sensing operation over a large area from the center of the wafer, and the signal processing unit 22 is concentrated on the outer area, because the signal processing and power supply are implemented in a minimum area, the center of gravity is skewed to one side.

A wafer transfer robot needs to transfer wafers to automatically use a process monitoring sensor manufactured in the form of a wafer in a semiconductor process facility. Furthermore, the weight and thickness need to be minimized in a form capable of being applied even in a narrow space. All structures need to be arranged in a structure that does not cause tilting during transportation or eccentricity in high-speed rotation in a spinner to be suitable for the center of gravity.

The conventional wafer-type sensors are as heavy as 1.5 kg, and thus have a structure in which spin is impossible and which is eccentric. Accordingly, it is impossible to use the conventional wafer-type sensors together with wafers. In contrast, the wafer-type sensor according to an embodiment of the inventive concept is light at about 200 g. In an embodiment of the inventive concept, when all the sensors included in the sensor unit 23, the signal processing unit 22, the power supply unit 21, and the protective structure, and a dummy element 30 are arranged, the manufacture may be made in consideration of the center of gravity.

Hereinafter, in an embodiment of the inventive concept, the wafer-type sensor unit 1 is disclosed. The wafer-type sensor unit 1 in which the electronic element 20 are arranged such that the center of gravity is provided to a center part is disclosed.

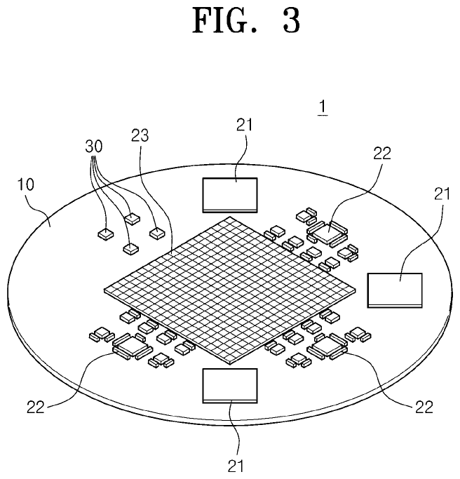

FIG. 2 is an example in the wafer-type sensor unit 1 according to an embodiment of the inventive concept.

As in FIG. 1, when the center of gravity in the wafer-type sensor unit 1 is skewed to the right, the center of gravity of the wafer-type sensor unit 1 may be allowed to be provided to the center part by additionally arranging other electronic elements 20 used in the wafer-type sensor unit 1.

According to an embodiment in FIG. 2, the center of gravity may be allowed to be provided to the center part by arranging the corresponding electronic elements 20 in a portion in a direction opposite to a direction in which the center of gravity is skewed.

According to an embodiment in FIG. 2, the center of gravity may be allowed to be provided to the center part by arranging the power supply unit 21 and the signal processing unit 22 in the empty portion in FIG. 1.

As in FIG. 2, when the electronic elements 20 included in the wafer-type sensor unit 1 are arranged, each of the electronic elements 20 may be arranged based on the principle of equal arrangement, such as trisection, quadrisection, or the like in consideration of the center of gravity.

In the case of FIG. 2, the center of gravity may be allowed to be provided to the center part through equal arrangement of quadrisection.

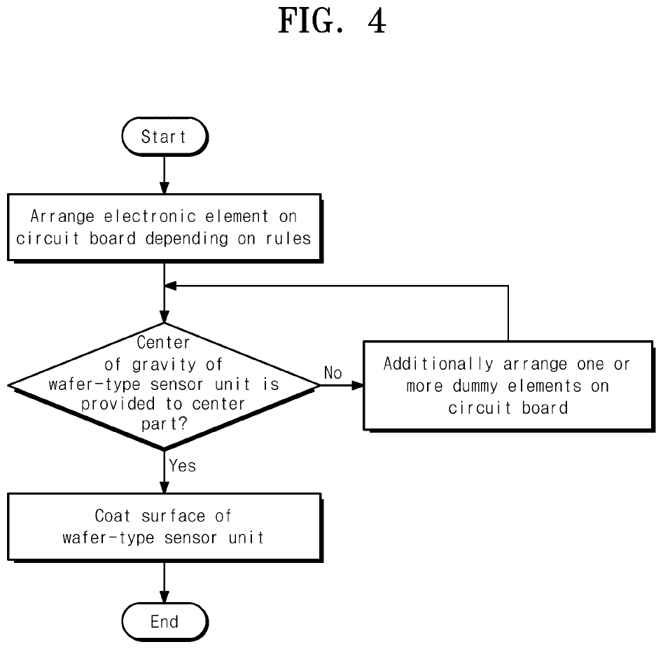

However, even though the equal arrangement is made, the center of gravity may deviate from the center part. In this case, the weight may be allowed to be uniformly distributed by including the dummy element 30 in the design, as in the embodiment of FIG. 3.

FIG. 3 is an example in the wafer-type sensor unit 1 according to another embodiment of the inventive concept.

As in the embodiment in the wafer-type sensor unit 1 according to FIG. 2, when the center of gravity is aligned to be provided to the center part by using the electronic element 20 to be used actually, the number of electronic elements 20 to be actually used is increased on the circuit board 10. For this reason, when the number of electronic elements 20 is increased on the single circuit board 10, overload may occur in terms of signal processing speed. Accordingly, to overcome these problems, the center of gravity may be allowed to be provided to a center part by arranging the one or more dummy elements 30 in the wafer-type sensor unit 1 according to an embodiment of the inventive concept.

The dummy element 30 may be an element manufactured to have a specific weight. The dummy element 30 may be provided in the form of a cube. The dummy element 30 may be a resin material. According to an example, the resin material may be PTFE or PEEK. The dummy element 30 may be a ceramic material. According to an example, the ceramic material may be Si, SiN, or Al₂O₃. The dummy element 30 may be a carbon-based material. According to an example, the carbon-based material may be Graphite or CFRP. According to an example, the average weight of the used dummy elements 30 may be about 1 g. The dummy element 30 may have a weight between 0.5 and 2 g depending on the size of the dummy element 30.

Alternatively, according to another example, the dummy element 30 may be the electronic element 20 such as an IC element, a battery element, or the like. As such, it is possible to avoid overload with another electronic element 20, using the electronic element 20 without wiring.

When there is a need for the dummy element 30 having a larger weight, a battery may be used as the dummy element 30 without a power connection. The weight of the battery may be from 20 g to 50 g depending on the capacity or size.

According to the embodiment of FIG. 3, the center of gravity of the wafer-type sensor unit 1 may be allowed to be concentrated on the center part, by arranging the dummy element 30 in a portion opposite to the portion where the center of gravity in FIG. 1 is skewed.

The arrangement structure of the electronic element 20 and the dummy element 30 shown in FIGS. 1 to 3 is only an example. The electronic element 20 may be arranged according to the arrangement rules of the electronic element 20. The dummy element 30 may be variously arranged on the circuit board 10, to the extent that the arrangement of the electronic element 20 and the operation of the electronic element 20 are not affected, and thus the center of gravity of the wafer-type sensor unit 1 may be concentrated on the center part.

FIG. 4 is a flowchart illustrating a manufacturing method of the wafer-type sensor unit 1 according to an embodiment of the inventive concept.

Referring to FIG. 4, in the manufacturing method of the wafer-type sensor unit 1 according to an embodiment of the inventive concept, the electronic elements 20 disposed on the wafer-type sensor unit 1 may be disposed depending on an element arrangement rule. The element arrangement rule refers to a rule for arranging the electronic elements 20 upon manufacturing a semiconductor circuit.

When the electronic elements 20 are positioned on the circuit board 10 of the wafer-type sensor unit 1 depending on the element arrangement rule, it is possible to determine whether the center of gravity of the wafer-type sensor unit 1 is provided to the center part of the sensor unit. According to an example, a method of determining the center of gravity may use the scheme of 4 run method. According to another example, the method may determine in which direction the center of gravity is located, through the spin of the wafer-type sensor unit 1. In addition to these methods, the center of gravity may be determined by using various methods of determining at which location the center of gravity is located, at the level of knowledge of those skilled in the art.

It is possible to determine the center of gravity of the wafer-type sensor unit 1 through the above determination methods; afterward, when the center of gravity is located at the center part of the sensor unit, the wafer-type sensor unit 1 may be completed by coating the surface of the wafer-type sensor unit 1.

When the wafer-type sensor unit 1 is manufactured, a control module (not shown) is connected to determine the location of the center of gravity in the wafer-type sensor unit 1.

It is determined whether the center of gravity of the wafer-type sensor unit 1 is located in the center part of the sensor unit. When the center of gravity is located in a position that is out of the center part of the sensor unit, the center of gravity of the wafer-type sensor unit 1 may be adjusted to be located at the center part by using the one or more dummy elements 30. The one or more dummy elements 30 are as described above.

The wafer-type sensor unit 1 may be manufactured such that the center of gravity of the wafer-type sensor unit 1 is located in the center part by arranging the one or more dummy elements 30 at a location away from the direction in which the center of gravity of the wafer-type sensor unit 1 is skewed.

The one or more dummy elements 30 are variously arranged on the circuit board 10 of the wafer-type sensor unit 1, and thus the center of gravity of the wafer-type sensor unit 1 may be allowed to be set to the center part.

It is possible to re-determine the center of gravity of the wafer-type sensor unit 1, in which the one or more dummy elements 30 are additionally arranged; when the center of gravity is located at the center part of the sensor unit, the wafer-type sensor unit 1 may be completed by coating the surface of the wafer-type sensor unit 1. The coating on the surface of the wafer-type sensor unit 1 may be a cover and case used to protect the electronic element 20 and the circuit board 10 from the external environment. This may be used as PI, Teflon film, or cover to minimize weight. The surface of the wafer-type sensor unit 1 may be coated with epoxy, PI, acrylic resin, or the like.

Wafer-type sensors that have started commercialization are heavy because the wafer-type sensors are manufactured including batteries and casing. However, in the inventive concept, it is possible to lighten the weight by performing a film or resin coating on a wafer-type sensor balanced by a dummy instead of the weight of casing. That is, the signal processing unit 22 may be protected by film or resin coating. In this case, the coating may be made on the front surface of the circuit board 10, or all except for the sensor unit 23 may be coated.

Although the embodiments of the inventive concept have been described above, it should be understood that the embodiments are provided to help with comprehension of the inventive concept and are not intended to limit the scope of the inventive concept and that various modifications and equivalent embodiments can be made without departing from the spirit and scope of the inventive concept. The drawings provided in the inventive concept are merely showing an optimal embodiment of the inventive concept. The technical protection scope of the inventive concept will be defined by the technical spirit of the appended claims, the scope and spirit of the inventive concept is not limited to the wording of the claims, and it is to be understood that the technical value substantially affects the equivalent scope of the inventive concept.

According to an embodiment of the inventive concept, a wafer-type sensor unit of which the center of gravity is capable of being concentrated on a center part may be provided.

According to an embodiment of the inventive concept, a wafer-type sensor unit may be applied to various facilities such that the center of gravity of the wafer-type sensor unit may be concentrated on the center part.

Effects of the inventive concept are not limited to the above-described effects, and any other effects not mentioned herein may be clearly understood from this specification and the accompanying drawings by those skilled in the art to which the inventive concept pertains.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

1. A wafer-type sensor unit comprising:
a circuit board; and
an electronic element including a sensor installed on the circuit board,
wherein the electronic element is disposed on the circuit board such that a center of gravity of the wafer-type sensor unit is provided to a center part of the sensor unit.

2. The wafer-type sensor unit of claim 1, wherein the electronic element includes:
a power supply unit; and
a signal processing unit configured to process a signal on the circuit board.

3. The wafer-type sensor unit of claim 2, further comprising:
one or more dummy elements installed on the circuit board.

4. The wafer-type sensor unit of claim 3, wherein the one or more dummy elements are elements having a specific weight.

5. The wafer-type sensor unit of claim 4, wherein a wiring is not connected to the one or more dummy elements.

6. The wafer-type sensor unit of claim 4, wherein the elements having the specific weight are made of one of resin, ceramic, and carbon as a raw material.

7. The wafer-type sensor unit of claim 3, wherein the one or more dummy elements are disposed on the circuit board such that the center of gravity of the wafer-type sensor unit in which the one or more dummy elements are arranged is provided to the center part of the sensor unit.

8.-10. (canceled)

11. A wafer-type sensor unit comprising:
a circuit board;
an electronic element including a sensor installed on the circuit board; and
one or more dummy elements installed on the circuit board,
wherein the electronic element and the one or more dummy elements are arranged and provided such that a center of gravity of the wafer-type sensor unit is provided to a center part of the sensor unit.

12. The wafer-type sensor unit of claim 11, wherein the electronic element includes:
a power supply unit; and
a signal processing unit configured to process a signal on the circuit board.

13. The wafer-type sensor unit of claim 12, wherein the one or more dummy elements are elements having a specific weight.

14. The wafer-type sensor unit of claim 13, wherein a wiring is not connected to the one or more dummy elements.

15. The wafer-type sensor unit of claim 13, wherein the elements having the specific weight are made of one of resin, ceramic, and carbon as a raw material.
